(19) United States
(12) Patent Application Publication
(10) Pub. No.: US 2026/0147963 A1
(43) Pub. Date: May 28, 2026

(54) METHODS AND SYSTEMS FOR GENERATING PARAMETERIZED DATA FOR PROCESSING BY PHYSICS SIMULATION ENGINES AND BY ARTIFICIAL INTELLIGENCE ENGINES

(71) Applicant: Pasteur Labs, Inc., Brooklyn, NY (US)

(72) Inventors: Alexander Lavin, Brooklyn, NY (US); Alex Kaszynski, Brooklyn, NY (US); Diego Fernando Andrade, Brooklyn, NY (US); Dion Hafner, Brooklyn, NY (US)

(21) Appl. No.: 19/394,999

(22) Filed: Nov. 20, 2025

Related U.S. Application Data
(60) Provisional application No. 63/723,692, filed on Nov. 22, 2024.

(51) Int. Cl. G06F 30/27

(52) U.S. Cl. CPC G06F 30/27

(57) ABSTRACT

A method for generating data for and processing data by at least one physics simulation engine and at least one artificial intelligence engine includes automatically generating, by a data processing engine, a parameterization representing at least one physics simulation dataset. The data processing engine transmits, to a computer aided engineering (CAE) simulation engine, the generated parameterization. The CAE simulation engine generates at least one model of a physical asset. The data processing engine modifies data associated with the at least one model of the physical asset for processing by an artificial intelligence (AI) engine. The data processing engine provides, to the AI engine, access to the generated parameterization, the modified data, and the at least one model of the physical asset. The AI engine executes at least one workflow using the provided data and generates and transmits to the CAE simulation engine at least one recommendation for improving subsequent models.

### CROSS-REFERENCE TO RELATED APPLICATIONS

This application claims priority from U.S. Provisional Patent Application No. 63/723,692 , filed on Nov. 22, 2024, entitled “Methods and Systems for Generating and Implementing Pipelines for differentiable physics, data-driven computing, and continuous optimization in Computer-Aided Engineering,” which is hereby incorporated by reference.

### BACKGROUND

The disclosure relates to methods for generating data for processing by different types of engines. More particularly, the methods and systems described herein relate to functionality for generating parameterized data for processing by physics simulation engines and by artificial intelligence engines.

Conventionally, computational approaches to modeling and simulating physics (in diverse domains of science and engineering, including for use-cases such as design of experiment, data analysis, predictive modeling, optimization, causal discovery and reasoning, and more) are typically incompatible with data and software for machine learning, artificial intelligence, and optimization; the former typically lacks an ability to use or maintain gradient information that is essential for the latter. Because the methods and algorithms of computational physics software are not compatible with differentiable software using gradient-based data, which typically underlies deep learning and other types of artificial intelligence software, conventional software typically fails to provide gradient-based information communicated between computational physics engines and machine learning engines. Therefore, there is a need for technological tools that enable an exchange and propagation of information between computational physics engines and machine learning engines.

### BRIEF SUMMARY

In one aspect, a method for generating data and processing the generated data by at least one physics simulation engine and at least one artificial intelligence engine includes automatically generating, by a data processing engine executing on a computing device, a parameterization representing at least one physics simulation dataset for processing by a modified computer aided engineering (CAE) simulation engine and by an artificial intelligence (AI) engine, wherein the modified CAE simulation engine is modified to process data exchanged with the AI engine, and wherein the AI engine executes at least one machine learning model. The method includes transmitting, by the data processing engine, to the modified CAE simulation engine, the generated parameterization. The method includes generating, by the modified CAE simulation engine, at least one model of a physical asset. The method includes modifying, by the data processing engine, data associated with the at least one model of the physical asset for processing by the AI engine. The method includes providing, by the data processing engine, to the AI engine, access to the generated parameterization, to the modified data, and to the at least one model of the physical asset. The method includes executing, by the AI engine, at least one workflow using the generated parameterization, the modified data, and the at least one model of the physical asset. The method includes generating, by the AI engine, at least one recommendation associated with the physical asset. The method includes transmitting, by the AI engine, to the modified CAE simulation engine, data to improve a subsequently generated second model of the physical asset. The method includes displaying, by the computing device, to a user, at least one of the at least one model of the physical asset and the generated recommendation.

### BRIEF DESCRIPTION OF THE DRAWINGS

The foregoing and other objects, aspects, features, and advantages of the disclosure will become more apparent and better understood by referring to the following description taken in conjunction with the accompanying drawings, in which:

FIGS. 1A-1H are block diagrams depicting embodiments of a system for generating parameterized data for processing by physics simulation engines and by artificial intelligence engines;

FIGS. 2A-2B are flow diagrams depicting embodiments of a method for generating parameterized data for processing by physics simulation engines and by artificial intelligence engines; and

FIGS. 3A-3C are block diagrams depicting embodiments of computers useful in connection with the methods and systems described herein.

### DETAILED DESCRIPTION

Conventional computer aided engineering (CAE) data, including assets such as, by way of example, computer aided design (CAD) models and computational fluid dynamics (CFD) simulations, are typically ill-suited for machine learning models and incompatible with data-oriented software systems; however, functionality for generating data based on such CAE data that is processable by AI engines may result in improved performance in engineering design. Therefore, the methods and systems described herein provide functionality for generating parameterized data for processing by physics simulation engines and by artificial intelligence (AI) engines. The methods and systems described herein include functionality for enabling an exchange of parameterized data between CAE engines and AI engines, which provide rich CAE simulation datasets to engines for generating ML-enabled solutions. Such functionality may provide functionality for enabling data generation in automated, scalable, generalizable manner that enables AI workflows, applications, and end-to-end engineering systems. Such functionality may enable execution of applied mathematics software for information-rich coordination between previously-incompatible classes of modeling and simulation. Such functionality may be incorporated into auto-differentiating software with computational primitives for causal and probabilistic machine learning (ML), purpose-built for tools providing, for example, and without limitation, modeling, simulation, and analysis (MS&A) in engineering physics and cyber-physical systems. Such functionality may provide modular, composable, interoperable solutions bridging computational physics and machine learning, and optionally, their respective extensions. Such functionality may be referred to, in some embodiments, as differentiable physics programming (DPP) and may include functionality for modeling in previously constrained fields such as, without limitation, computational design and engineering, scientific computing, digital engineering and manufacturing. As will be understood by those of skill in the art, CAE tools may include, without limitation, computer aided design (CAD) tools, computational fluid dynamics (CFD) tools, finite element analysis tools (FEA), computer aided manufacturing (CAM) tools, and other computer aided simulation tools, which may also be referred to herein as CAx tools.

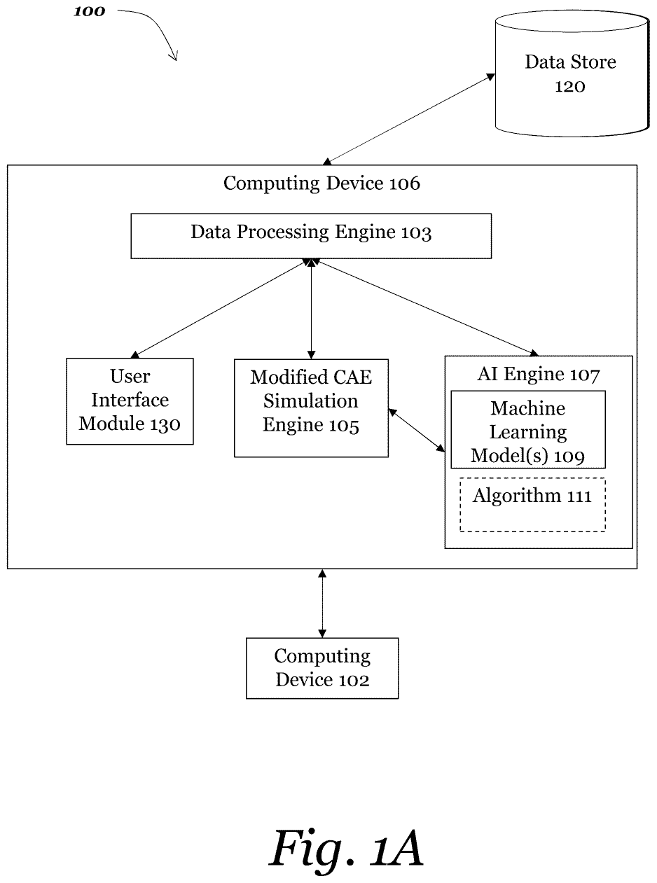

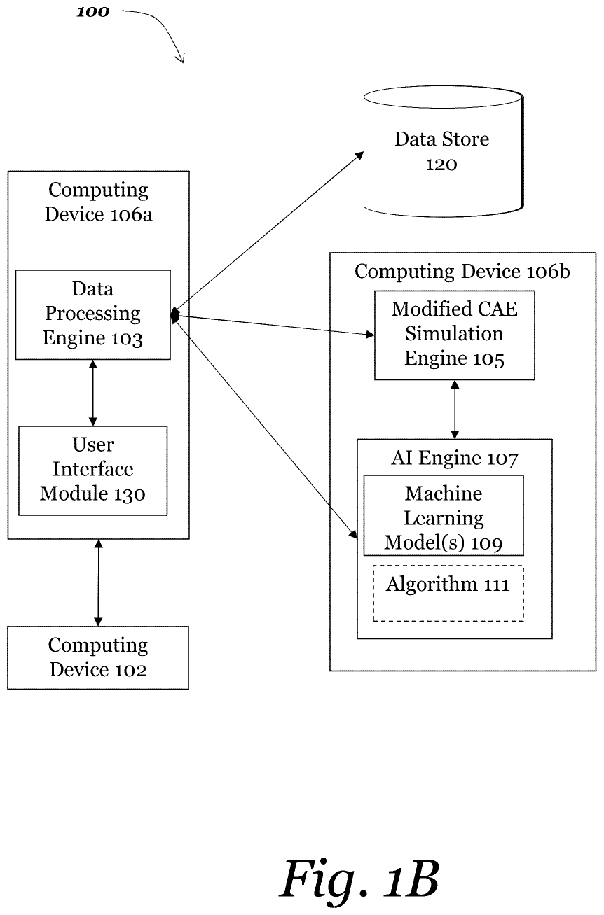

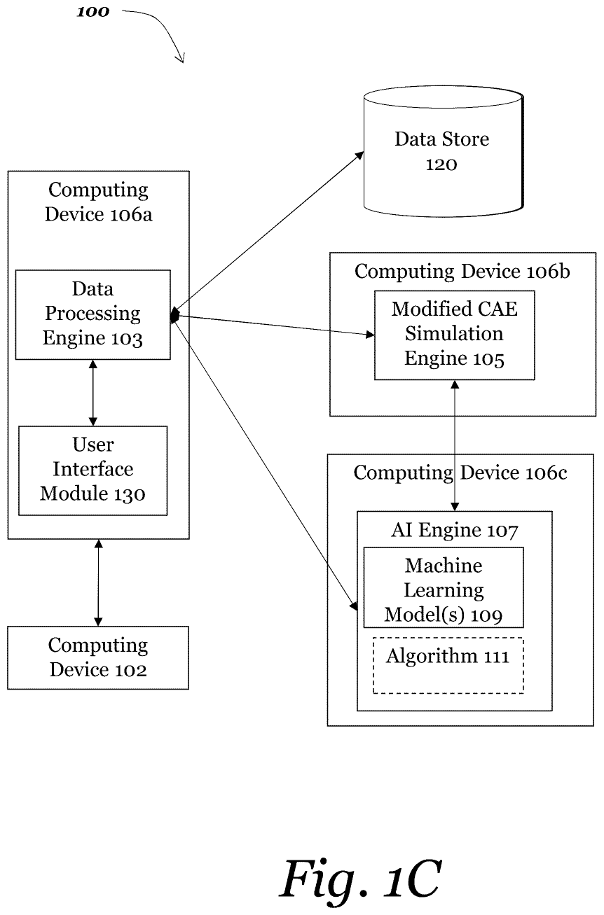

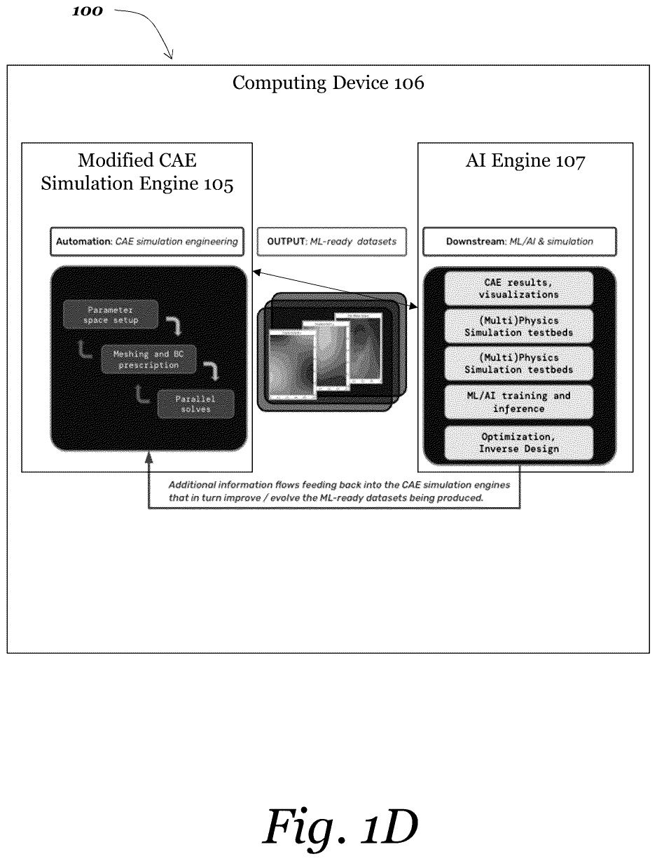

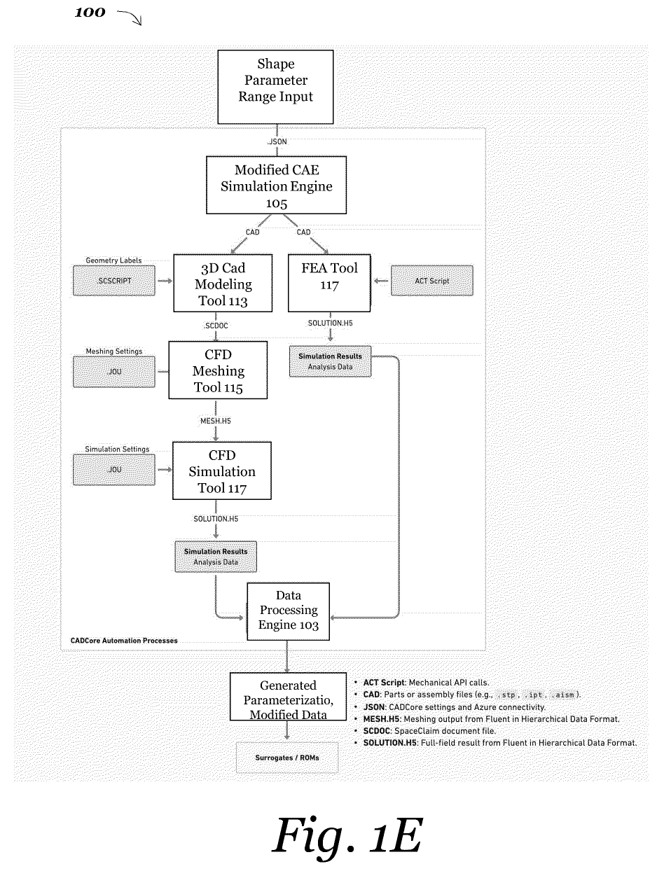

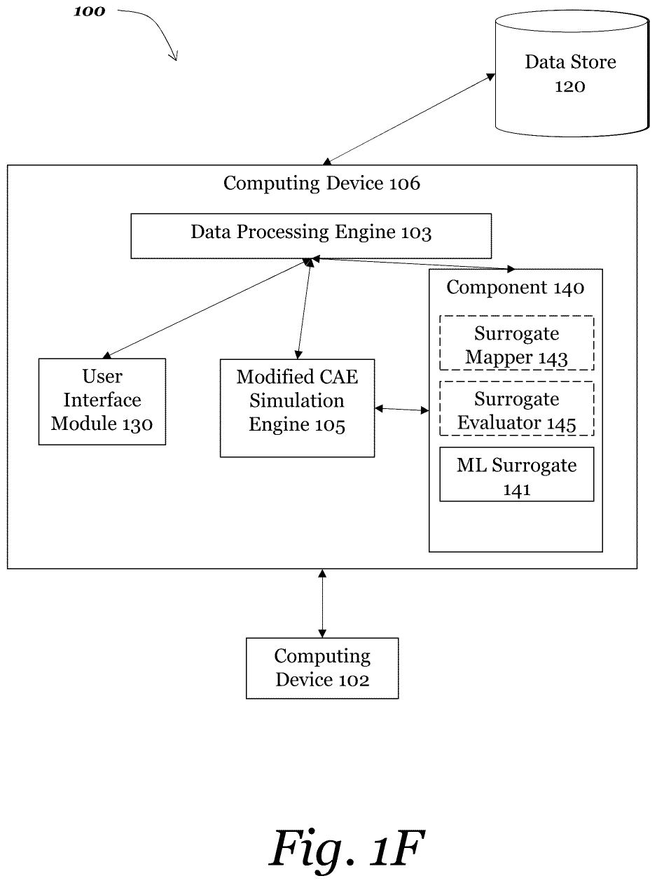

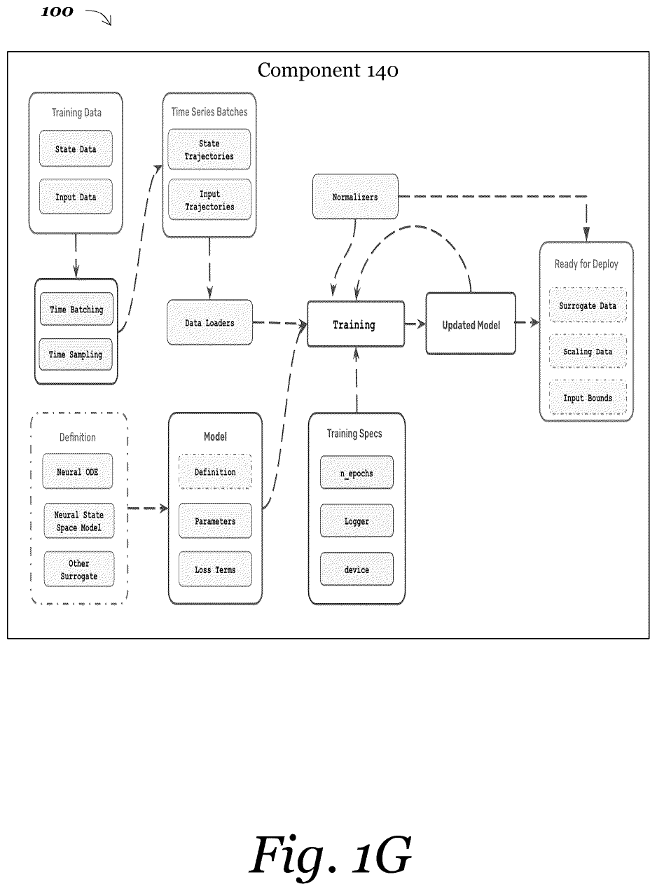

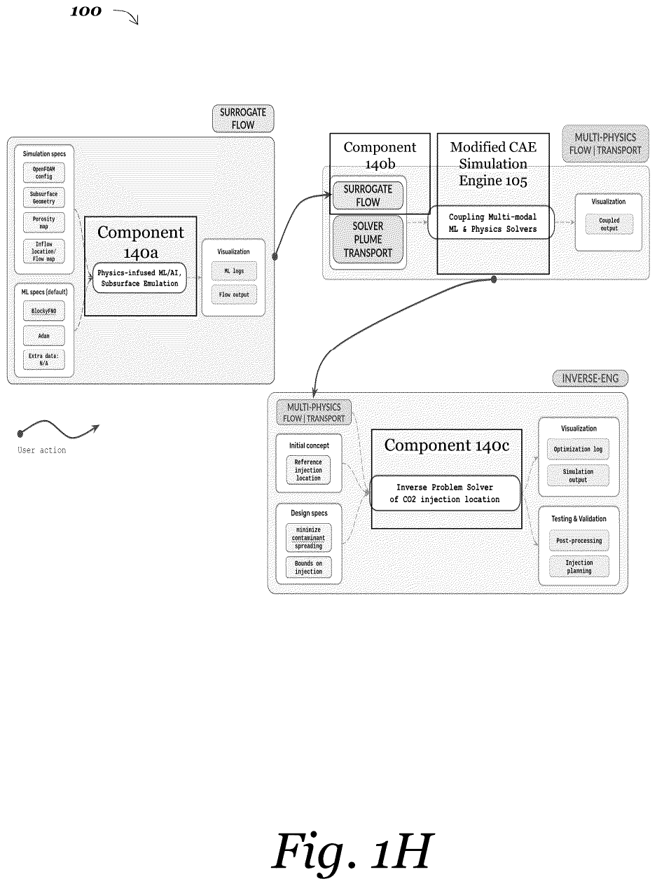

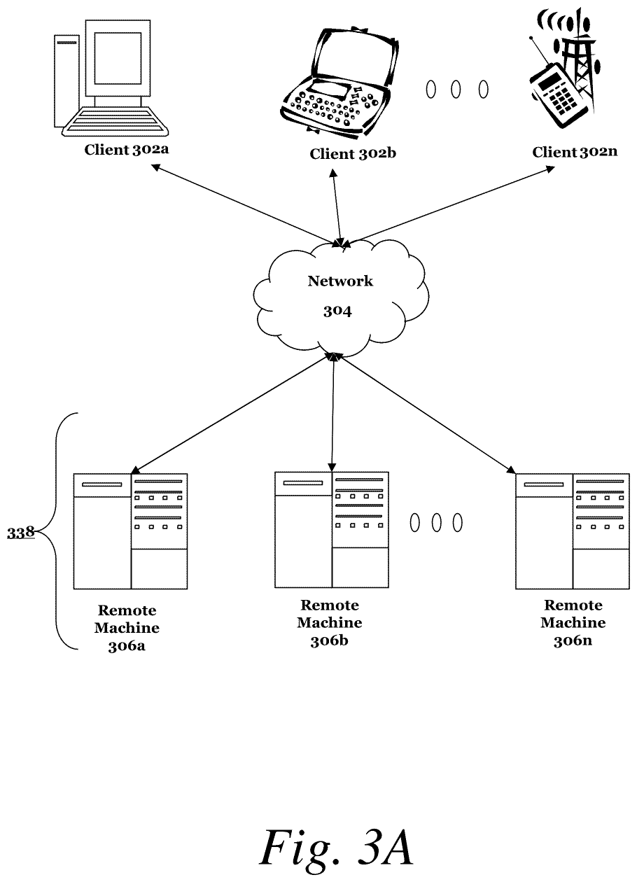

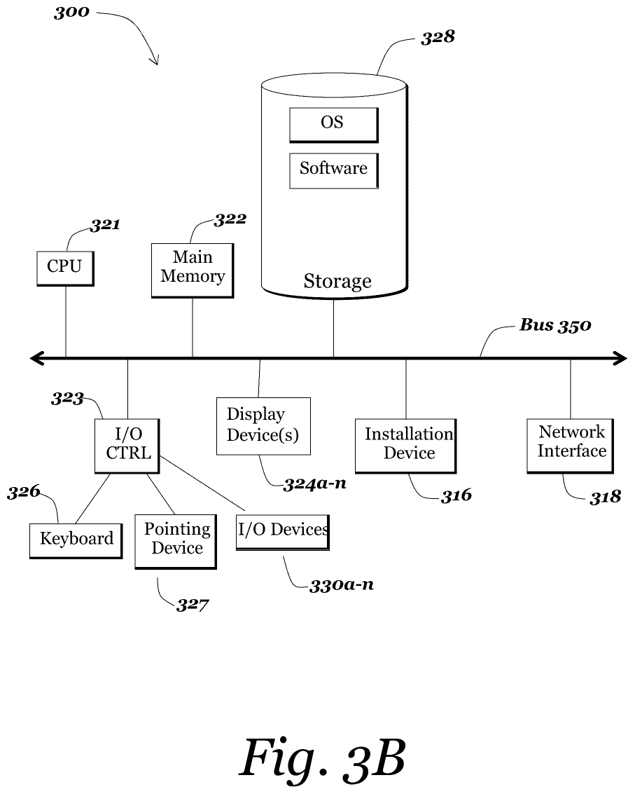

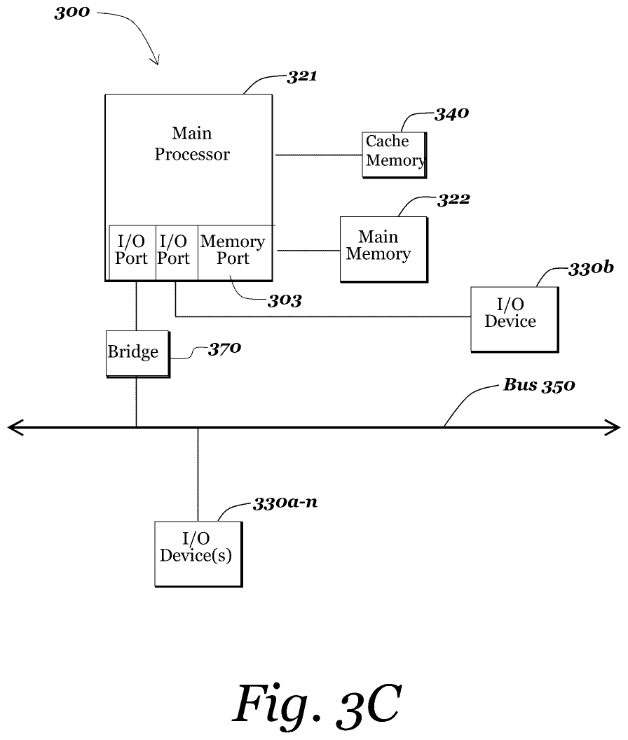

Referring now to FIG. 1A, a block diagram depicts one embodiment of a system for generating parameterized data for processing by physics simulation engines and by AI engines. In brief overview, the system 100 includes a computing device 102, a computing device 106, a data processing engine 103, a modified CAE simulation engine 105, an AI engine 107, a machine learning model 109, a data store 120, and a user interface module 130, and, optionally, at least one algorithm 111. The computing device 106 may be a modified type or form of computing device (as described in greater detail below in connection with FIGS. 3A-3C) that has been modified to execute instructions for providing the functionality described herein; these modifications result in a new type of computing device that provides a technical solution to problems rooted in computer technology, such as technology for generating a parameterization of a data set of a first type that is capable of being processed by two different kinds of previously incompatible systems, such as simulation engines and AI engines.

The data processing engine 103 may be provided as a software component. The data processing engine 103 may be provided as a hardware component. The computing device 106 may execute the data processing engine 103. The data processing engine 103 may execute functionality for accessing physics simulation datasets. The data processing engine 103 may execute functionality for generating a parameterization of one or more physics simulation datasets.

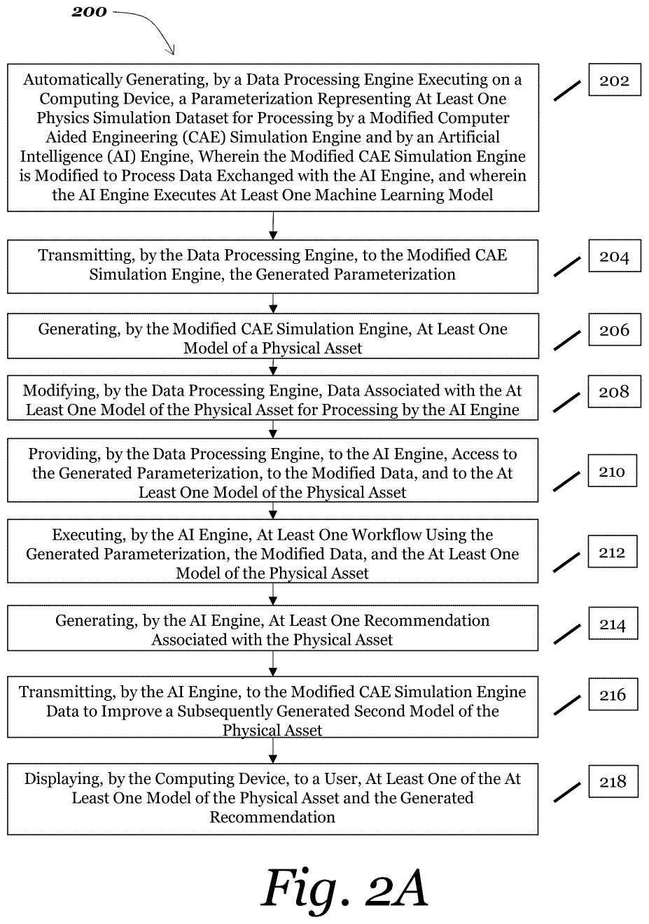

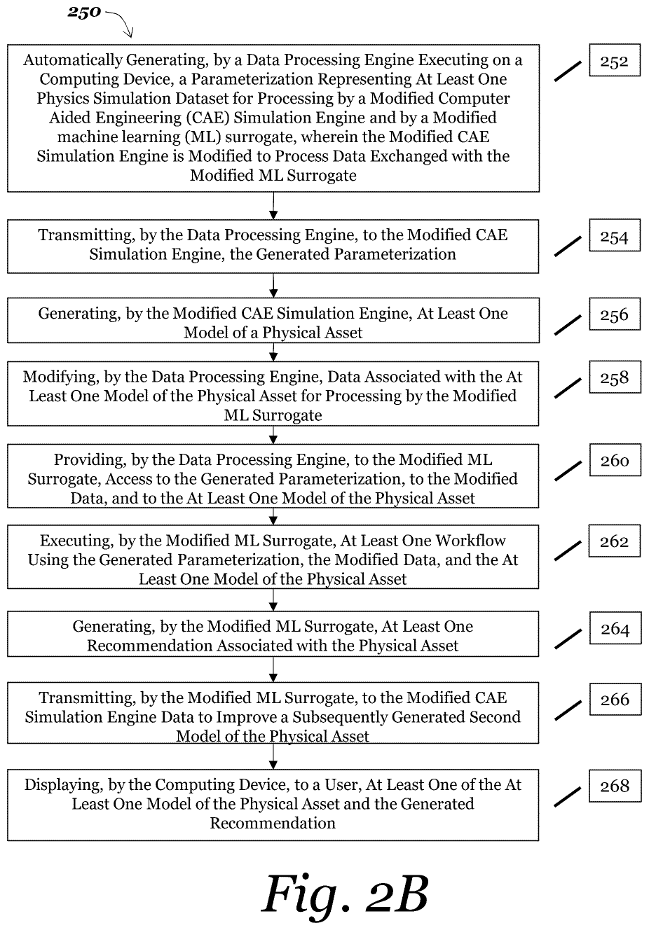

In some embodiments, the data processing engine 103 may execute one or more automation processes that address a digital engineering bottleneck facing conventional systems: given at least one CAD file (and optionally accompanying computational engineering information, including additional CAE files), the manual procedure for taking the geometric information from the CAD file(s) and their modifications, which themselves must be extracted or retrieved from at least one CAE software application as a set of modeling parameters, executing one or more physics simulations that produce experimental output, while keeping the initial modeling parameters and any physics simulation parameters fixed and consistent, where that experimental output is “ML-ready” for use in AI/ML/optimization workflows. As such, the data processing engine 103 takes as input existing parameterized CAD files, their corresponding feature characterization (such as boundary conditions (BCs) and simulation specifications/setups (like journal files in the case of some simulations)) and is configured to have access to the CAD and simulation tools licensed to at least one operator (which may be one or more human users or a machine process) executing the data processing engine 103. Given any new set of CAD (or CAE) parameters, in some embodiments, the data processing engine 103 may automatically execute a workflow including a step of receiving one or more CAD parameters, generating a new CAD, executing a feature prescription process, executing a meshing operations, executing a simulation or directing execution of a simulation, and receiving simulation output files; the simulation output files and associated data may be converted into data processable by an AI engine 107 as will be described in further detail below in connection with FIG. 2A.

The data processing engine 103 may include or be in communication with a component for converting data including, without limitation, surface data, volumetric data, mesh data, point clouds, implicit data, and spatial data files, all of which may be processed as (or in sync with) temporal information by the data processing engine 103.

The data processing engine 103 may optionally include or be in communication with a component for preprocessing data. The component for preprocessing data may provide functionality for dimensionality reduction, cleaning functionality, and/or visualization functionality.

The modified CAE simulation engine 105 may be provided as a software component. The modified CAE simulation engine 105 may be provided as a hardware component. The computing device 106 may execute the modified CAE simulation engine 105. The modified CAE simulation engine 105 may be in communication with the AI engine 107.

The modified CAE simulation engine 105 may be a general-purpose simulation engine modified to include functionality for processing parameterized data sets, which conventional simulation engines lack.

The modified CAE simulation engine 105 may include functionality for integrating with one or more Application Programming Interfaces to enable communication and data exchange with one or more CAX tools and/or external applications and/or services. The modified CAE simulation engine 105 may include or be in communication with at least one module providing a user interface to receive data for handling CAE simulation setup and execution and/or for visualizing one or more results. The modified CAE simulation engine 105 may include modified file handling to support a plurality of configurations of CAx tools, CAx data types, and/or CAx file formats. The modified CAE simulation engine 105 may include modified file handling for supporting a variety of computing architectures such as, without limitations, local computing and distributed computing. The modified CAE simulation engine 105 may include functionality enabling command-line interface (CLI) access to one or more CAx tool settings from within the modified CAE simulation engine 105.

The modified CAE simulation engine 105 may execute a plurality of software tools to generate the at least one model of the physical asset, each of which may be of the same type of software tool or different types of software tools. The plurality of software tools may be configured to have a plurality of settings of the same type. The plurality of software tools may be configured to have a plurality of settings of different types. The modified CAE simulation engine 105 may execute CAE tools such as, without limitations, program and language transformations supporting Python, C#, Java, and bash scripting. The modified CAE simulation engine 105 may execute software tools such as physics solvers, which may, optionally, include custom implementations of physics solvers instead of, or in addition to, commercially available physics solvers such as the physics solvers manufactured by ANSYS, Inc., of Canonsburg, PA.

The modified CAE simulation engine 105 may include one or more interfaces for CAE tooling interoperability and programmatic extensibility, including, without limitation, endpoints and command-line interfaces.

The AI engine 107 may be provided as a software component. The AI engine 107 may be provided as a hardware component. The AI engine 107 may include or be in communication with a hardware component such as a graphics processing unit or other unit in a computing device, including those which may perform parallel processing tasks. The computing device 106 may execute the AI engine 107.

The AI engine 107 may execute at least one machine learning model 109. The AI engine 107 may optionally execute at least one algorithm 111 instead of or in addition to the at least one machine learning model 109. The at least one algorithm 111 may be an algorithm for optimization. The at least one algorithm 111 may be an algorithm for dimensionality reduction. The at least one algorithm 111 may be an algorithm for noise injection. The at least one algorithm 111 may be an algorithm for model pruning and/or dropout. The at least one algorithm 111 may be an algorithm for sampling. The at least one algorithm 111 may be an algorithm for uncertainty estimation. The AI engine 107 may be in communication with the modified CAE simulation engine 105. The execution of the at least one machine learning model 109 may include, but need not strictly imply, a training model; that is, the method 200 described below may execute at a time at which the AI engine 107 is undergoing a training process or the method 200 described below may execute at a time subsequent to a time at which the AI engine 107 has completed a training process. The AI engine 107 may include a suite of interoperable AI/ML models. In some embodiments, as a result of the data processing engine 103 generating “ML-ready” datasets, a plurality of types of AI/ML models may receive the ML-ready datasets as inputs without requiring additional data engineering or model engineering.

Referring back to FIG. 1A, the computing device 106 may include or be in communication with the data store 120. The data store 120 may store datasets related to physics simulations. The data store 120 may be an ODBC-compliant database. For example, the data store 120 may be provided as an ORACLE database, manufactured by Oracle Corporation of Redwood Shores, CA. In other embodiments, the data store 120 can be a Microsoft ACCESS database or a Microsoft SQL server database, manufactured by Microsoft Corporation of Redmond, WA. In other embodiments, the data store 120 can be a SQLite database distributed by Hwaci of Charlotte, NC, or a PostgreSQL database distributed by The PostgreSQL Global Development Group. In still other embodiments, the data store 120 may be a custom-designed database based on an open source database, such as the MYSQL family of freely available database products distributed by Oracle Corporation of Redwood City, CA. In other embodiments, examples of data stores include, without limitation, structured storage (e.g., NoSQL-type databases and BigTable databases), HBase databases distributed by The Apache Software Foundation of Forest Hill, MD, MongoDB databases distributed by 10Gen, Inc., of New York, NY, an AWS DynamoDB distributed by Amazon Web Services and Cassandra databases distributed by The Apache Software Foundation of Forest Hill, MD. In further embodiments, the data store 120 may be any form or type of data store.

Although, for ease of discussion, the data processing engine 103, the modified CAE simulation engine 105, the AI engine 107, the data store 120, and the user interface module 130 are described in FIGS. 1A-1H as separate modules, it should be understood that this does not restrict the architecture to a particular implementation. For instance, these components may be encompassed by a single circuit or software function or, alternatively, distributed across a plurality of computing devices. As shown in FIG. 1A, the computing device 106 executes the data processing engine 103, the modified CAE simulation engine 105, the AI engine 107, and the user interface module 130. FIG. 1B depicts another embodiment in which a computing device 106a executes the data processing engine 103 and the user interface module 130 and a computing device 106b executes the modified CAE simulation engine 105 and the AI engine 107. FIG. 1C depicts yet another embodiment in which a computing device 106a executes the data processing engine 103 and the user interface module 130, a computing device 106b executes the modified CAE simulation engine 105, and a computing device 106c executes the AI engine 107.

Referring now to FIG. 1D, the modified CAE simulation engine 105 may include functionality for receiving inputs such as geometries and simulation set-up data. The modified CAE simulation engine 105 may include functionality such as, without limitation, functionality for executing mechanics simulations, functionality for executing thermal simulations, functionality for executing plasmas simulations, functionality for executing electromagnetic simulations, physics solvers, forward models, implicit geometries, and meshes. The modified CAE simulation engine 105 may include functionality for generating machine learning (ML)-ready datasets. As depicted in FIG. 1D, the AI engine 107 may receive the ML-ready dataset, CAE results, CAE visualizations, and other data associated with models generated by the modified CAE simulation engine 105. The AI engine 107 may execute functionality for generating physics simulation testbeds, for optimization, and/or for inverse design. The AI engine 107 may execute functionality for training and inference to improve the ML/AI model(s) 109. The AI engine 107 may execute functionality for providing to the modified CAE simulation engine 105 information that may be used to improve and/or evolve the ML-ready datasets produced by the modified CAE simulation engine 105.

Referring now to FIG. 2A, in brief overview, a block diagram depicts one embodiment of a method 200 for generating data and processing the generated data by at least one physics simulation engine and at least one artificial intelligence engine. The method 200 includes automatically generating, by a data processing engine executing on a computing device, a parameterization representing at least one physics simulation dataset for processing by a modified computer aided engineering (CAE) simulation engine and by an artificial intelligence (AI) engine, wherein the modified CAE simulation engine is modified to process data exchanged with the AI engine, and wherein the AI engine executes at least one machine learning model (202). The method 200 includes transmitting, by the data processing engine, to the modified CAE simulation engine, the generated parameterization (204). The method 200 includes generating, by the modified CAE simulation engine, at least one model of a physical asset (206). The method 200 includes modifying, by the data processing engine, data associated with the at least one model of the physical asset for processing by the AI engine (208). The method 200 includes providing, by the data processing engine, to the AI engine, access to the generated parameterization, to the modified data, and to the at least one model of the physical asset (210). The method 200 includes executing, by the AI engine, at least one workflow using the generated parameterization, the modified data, and the at least one model of the physical asset (212). The method 200 includes generating, by the AI engine, at least one recommendation associated with the physical asset (214). The method 200 includes transmitting, by the AI engine, to the modified CAE simulation engine, data to improve a subsequently generated second model of the physical asset (216). The method 200 includes displaying, by the computing device, to a user, at least one of the at least one model of the physical asset and the generated recommendation (218).

Referring now to FIG. 2A, in greater detail and in connection with FIGS. 1A-H, the method 200 includes automatically generating, by a data processing engine 103 executing on a computing device 106, a parameterization representing at least one physics simulation dataset for processing by a modified computer aided engineering (CAE) simulation engine 105 and by an artificial intelligence (AI) engine 107, wherein the modified CAE simulation engine 105 is modified to process data exchanged with the AI engine 107, and wherein the AI engine 107 executes at least one machine learning model (202). Generating the parameterization may include auto-parameterizing an input to or an output from the modified CAE simulation engine 105 or both; auto-parameterization enables the modified CAE simulation engine 105 to work with ML data.

To generate the parameterization (which may be referred to as output including ML-ready datasets), the data processing engine 103 may execute a data conversion method. The data conversion method may include converting the simulation data into a novel, universal data format that is agnostic as to the source of the simulation data; the data format may comply with computational engineering standards and SWE best-practices. The data format may be compatible with any CAE tool, physics solver, ML/AI framework, Machine Learning Operations (MLOps) processes, Continuous Integration/Continuous Deployment for MLOps (CI/CD for MLOps) systems, and/or Model-based systems engineering (MBSE) interface.

During execution of the data conversion method, the data processing engine 103 may generate a converted version of the simulation data that includes a fixed and transparent data structure, such as a nested structure of containers. In one embodiment, by way of example and without limitation, a nested structure may be implemented in the PYTHON programming language developed by the Python Software Foundation of Fredericksburg, VA; for example, the data processing engine 103 may use a pytree structure during the data conversion method. The data processing engine 103 may generate a data structure storing the converted data that represents diverse geometric data formats and structures with semantics, such as without limitation, volumetric and surface meshes, point clouds, b-splines and so on. The data processing engine 103 may seamlessly represent and work with arbitrary-rank tensor field data (attached to either points or cells), and compute gradient/divergence/curl/Laplacians of field data directly on mesh manifolds.

During conversion of simulation data, the data processing engine 103 may coalesce and label one or more modeling parameters. During conversion of simulation data, the data processing engine 103 may coalesce and label one or more physics simulation parameters. During conversion of simulation data, the data processing engine 103 may coalesce and label one or more multi-physics simulation parameters. The data processing engine 103 may generate a representation of one or more parameters as variables that may be provided as input to the AI engine 107 and that are in a format that may be processed by the AI engine 107. The variables may be set for an AI/ML model to use as inputs, constraints to maintain physics consistency, bounds on the modeling or optimization spaces, training and inference objectives, or unknowns to estimate.

Generating the parameterization may include generating geometric data transformations for automation e.g. Python scripting for geometry manipulation with any standard CAD file format, and support for meshes, SDF, implicit geometries, and point clouds. Closed-loop information flows may be provided, which may enable end-to-end differentiable programming with multi-physics models and data.

The method 200 includes transmitting, by the data processing engine, to the modified CAE simulation engine, the generated parameterization (204). The data processing engine 103 may transmit the generated parameterization to the modified CAE simulation engine 105. The data processing engine 103 may provide the modified CAE simulation engine 105 with access to the generated parameterization.

The method 200 includes generating, by the modified CAE simulation engine, at least one model of a physical asset (206). As described above in connection with FIGS. 1A-1C, the modified CAE simulation engine 105 may execute a plurality of software tools. The modified CAE simulation engine 105 may execute a plurality of physics solvers to generate the at least one model of the physical asset. In such an embodiment, the modified CAE simulation engine may orchestrate an execution of the plurality of physics solvers, based upon an output of processing the generated parameterization. The modified CAE simulation engine may execute a plurality of computational engineering tools to generate the at least one model of the physical asset. In such an embodiment, the modified CAE simulation engine may orchestrate an execution of the plurality of computational engineering tools, based upon an output of processing the generated parameterization.

By way of example, and without limitation, in one embodiment, the generated parameterization may include a model that may load parameters, execute (e.g., via automated execution of a script embedded in the model), and generate output data. Such a parameterized model may execute from the command line. Such a parameterized model may run one or more studies. Execution of such a parameterized model may include execution of flow regimes selected for execution by a user and/or an automated agent, including, without limitation, steady-state, unsteady, laminar, and/or turbulent flows, involving one or multiple liquids (fluid density and viscosity, etc.) and fluid-structure interactions (FSI). The exported model outputs may include a computer aided design (CAD) of a geometry, a mesh, and a range of output data including quantities of interest with regards to the physics being simulation (e.g. degree of mixing, thermal conductivity, deformations and other quantities of interest). The generated parameterization may include an executable model that has modularity for multiphysics dataflows, for instance for interchanging or combining tools. For example, the executable model may support interchanging or combining tools such as tools used for computational fluid dynamics (CFD) simulations such as those manufactured by manufactured by ANSYS, Inc., of Canonsburg, PA, finite element analysis (FEA) software such as those manufactured by ANSYS, Inc., of Canonsburg, PA. As another example, the executable model may support the interchange of CFD packages such as, for example, CFD simulation software such as the SIMCENTER STAR-CCM+ manufactured by Siemens Aktiengesellschaft of Munich, Germany, and open-source CFD software such as the OpenFOAM CFD software package manufactured by OpenCFD Ltd. of Berkshire, England.

The method 200 includes modifying, by the data processing engine, data associated with the at least one model of the physical asset for processing by the AI engine (208). The data processing engine 103 may modify the data as described above in connection with (202).

Referring now to FIG. 1E, a flow diagram depicts one embodiment of a system 100 for generating parameterized data for processing by physics simulation engines and by artificial intelligence engines. As depicted in FIG. 1E, inputs to the system 100 may be provided to the modified CAE simulation engine 105 directly (as, for example, the shape parameter range input in FIG. 1E is provided). As depicted in FIG. 1E, inputs to the system may be provided to a software tool executed by the modified CAE simulation engine 105, as, for example, the ACT scripts (e.g., output of API calls), geometry labels, meshing settings, parts files, assembly files, meshing output, document files, full-field results, simulation settings, and/or simulation results are provided. As depicted in FIG. 1E, in some embodiments, the data processing engine 103 receives data from the modified CAE simulation engine 105 and/or from one or more software tools executed by the modified CAE simulation engine 105 and modifies the data for processing by the AI engine 107. The modified data may include a model of the model (also referred to as a surrogate). The modified data may include a reduced order model (ROM) that approximates the model generated by the modified CAE simulation engine 105. As shown in the embodiment depicted by FIG. 1E, the modified CAE simulation engine 105 may be in communication with a 3D CAD modeling tool 113, a CFD meshing tool 115, and/or a CFD simulation tool 117.

FIG. 1E depicts non-limiting examples of the types of software tools the modified CAE simulation engine 105 may execute; the system 100 however is independent of any one specific task and the software tools executed by the modified CAE simulation engine 105 may vary based upon a particular task being executed. The modified CAE simulation engine 105 may for example select software tools for executing gradient-free shape optimization tasks (e.g., Bayesian optimization). In selecting and executing other tasks, the modified CAE simulation engine 105 may receive other types of input such as, for example, inputs such as Quantities of Interest, geometric formats, meshing types, labeling, volume extraction, material properties, iteration counts, convergence criteria, initial conditions, and/or boundary conditions.

The method 200 includes providing, by the data processing engine, to the AI engine, access to the generated parameterization, to the modified data, and to the at least one model of the physical asset (210). The data processing engine 103 may provide the AI engine 107 with access to the generated parameterization, to the modified data, and to the at least one model of the physical asset. The data processing engine 103 may transmit a copy of the generated parameterization, to the modified data, and to the at least one model of the physical asset to the AI engine 107. The data processing engine 103 may transmit one or more instructions for accessing the generated parameterization, to the modified data, and to the at least one model of the physical asset to the AI engine 107.

The method 200 includes executing, by the AI engine, at least one workflow using the generated parameterization, the modified data, and the at least one model of the physical asset (212). The AI engine may generate at least one output subsequent to execution of the at least one workflow using the generated parameterization, the modified data, and the at least one model of the physical asset. The AI engine may generate at least one output during execution of the at least one workflow using the generated parameterization, the modified data, and the at least one model of the physical asset. The AI engine may execute output including at least one inference. The AI engine may execute output including at least one prediction. The AI engine may execute output including at least one classification. The AI engine may execute output including at least one estimate of a level of confidence (e.g., a level of confidence in a prediction, a level of confidence in a recommendation, and/or a level of confidence in an output generated prior to generation by the AI engine of the at least one estimate of the level of confidence).

The method 200 includes generating, by the AI engine, at least one recommendation associated with the physical asset (214). The AI engine may generate a recommendation including an optimization for improving a level of performance of the physical asset.

The method 200 includes transmitting, by the AI engine, to the modified CAE simulation engine, data to improve a subsequently generated second model of the physical asset (216). Referring back to FIG. 1D, the AI engine 107 creates a feedback loop or other information flow. The methods and systems described herein may provide functionality for forward-backward information flows. This may include providing functionality for data assimilation, through which the system may iteratively update model states using observations generated by the AI engine 107. This may include providing functionality for model calibration including for calibrating CAE models, where CAD and other models may be updated to match downstream data (from the real-world). Such ML-ready physics information flows enable automated model updates with as-manufactured measurements, prototype and testbed performance measures, and environment parameters. This may include providing functionality for active learning, whereby information from downstream models may inform the selection of data upstream, which may mean informing the process for the automated parameterization of CAE inputs (geometries and simulation setups) in order to produce ML-ready datasets that represent the space of physics and/or the downstream learning/optimization tasks. This may include providing functionality for experiment designs. This may include providing functionality for inverse problem solving. This may include providing functionality for Bayesian inference and counterfactual reasoning.

The method 200 includes displaying, by the computing device, to a user, at least one of the at least one model of the physical asset and the generated recommendation (218). The computing device 106 may display the at least one of the at least one model of the physical asset and the generated recommendation directly to a user of the computing device 106. The computing device 106 may direct the display of the at least one of the at least one model of the physical asset and the generated recommendation to a user of a computing device 102. The computing device 106 may execute the user interface module 130 to generate the display, whether at the computing device 106 or at a second computing device, such as the computing device 102.

In some embodiments, the method 200 does not include displaying, by the computing device, to a user, at least one of the at least one model of the physical asset and the generated recommendation and instead the system executes without requiring a display of, or input to, a graphical user interface (e.g., the system 100 is provided as a “headless” system).

The AI engine 107 may calibrate the generated parameterization. The AI engine 107 may communicate with the modified CAE simulation engine 105 to exchange data used for calibrating, by the AI engine 107, the generated parameterization.

The AI engine 107 may calibrate the at least one model of the physical asset. The AI engine 107 may communicate with the modified CAE simulation engine 105 to exchange data used for calibrating, by the AI engine 107, the at least one model of the physical asset.

The methods and systems described herein may provide functionality for optimization, including substantially continuous optimization. Such optimization may include using output-to-input dataflows and intelligent multiphysics samplers. The output-to-input dataflows may be depicted as a feedback channel from the pipeline output data to the input setup. The intelligent multiphysics samplers may include a distinct class of algorithms that automatically provide exploration-exploitation recommendations in data spaces characterized by single-or multiple-physics, continuous or discrete time, geometric and hierarchical structures. The output-to-input dataflows and intelligent multiphysics sampler may enable the methods and systems described herein to improve the quality and value-add of data the system generates, optimizing the richness and quantity of data produced versus computational costs (in time, money, and other large-scale compute metrics). New approaches to CAE may be enabled as a result of implementing the methods and systems described herein, such as, for example, inverse design, structural optimization, and quantities-of-interest optimization. Continuity of dataflows may provide governance and versioning across modeling and simulation (M&S) toolsets that are currently disconnected; that is, the application of these continuous dataflows (or traces, threads) may enable much of what is referred to as a “digital thread”, including for features or uses of digital thread in manufacturing and supply chain sectors.

The methods and systems described herein may provide functionality for end-to-end gradient-based information flows for use by ML/AI with CAE datasets.

The methods and systems described herein may provide functionality for generating parameterizations of data sets to enable the transfer or generalization of existing models, algorithms, domain priors and other knowledge across CAE toolsets.

The methods and systems described herein may provide functionality for generating parameterizations of data sets to enable interaction between AI engines and CAE simulation engines. Implementation of the methods and systems described herein may enable industrial scale deployments of Machine Learning/AI for CAE, via pipeline parallelization, end-to-end workflow automation, and software design patterns for distributed computing.

In some embodiments, the methods and systems described herein may provide functionality, including software interfaces, that facilitate the computation and propagation of lossless gradient information representing spatial, temporal, geometric, and hierarchical data. Such data and the physics information such data encodes may enable improved scientific experimentation and the engineering of digital-physical systems, including in embodiments that implement machine learning and other forms of artificial intelligence. The improved Scientific Machine Learning (SciML) functionality provided by the methods and systems described herein may include processing units that provide improved components for execution in customizable optimization solution. In some embodiments, the system 100 includes a component that is an atomic processing unit. Such a component may have freedom of implementation; that is, may be free from constraints on selection of programming framework or language. Such a component may be free from constraints regarding computational hardware; that is, the components need not all be executed on the same type of hardware to execute collaboratively in downstream shared task pipelines. Such a component may be containerized. Such a component may provide an Application Programming Interface (API) endpoint. Such a component may be a machine learning (ML) surrogate, enabling improved functionality for differentiable emulation of physics processes. Such a component may encapsulate an ML surrogate. Such a component may encapsulate a software tool other than an ML surrogate.

Conventionally, simulation tools require significant time and computational power to execute a model and generate results. Therefore, implementation of a component that uses machine learning to emulate the functionality of such tools may result in improved ability to execute subsets of the functionality of conventional simulation tools or to generate an approximation of output that a simulation tool would generate if executed completely.

Referring now to FIG. 1F, a block diagram depicts one embodiment of a system for generating parameterized data for processing by physics simulation engines and by artificial intelligence engines. As shown in FIG. 1F, the modified CAE simulation engine 105 may be in communication with a component 140. The component 140 may execute a machine learning (ML) surrogate 141. The component 140 may enable customizable optimization solutions. By way of example, and without limitation, the component 140 may compute gradients of one or more ML surrogates 141 with respect to their inputs while tracking input-output labels and may return gradients of specific outputs with respect to specific inputs. The component 140 may obtain outputs from the modified CAE simulation engine 105. The component 140 may provide functionality for formulating optimization problems and integrating with optimization frameworks. The component 140 may provide improved functionality for executing workflows that require gradient information, such as optimization for engineering design, inverse problem solving, experiment design, parallelization, distributed computing, batch and online modes, continuous integration and/or continuous updating. In some embodiments, the ML surrogate 141 may be a scientific computing and ML/AI component seamlessly wrapped with a Python API into a software container (e.g., the component 140) that provides standardized interfaces and embedded automatic differentiation.

The component 140 may optionally include a surrogate mapper 143. The component 140 may optionally include a surrogate evaluator 145. In some embodiments, a surrogate mapper 143 executed by the component 140 may receive inputs and provide a first subset of the inputs to the surrogate evaluator 145 optionally executed by the component 140, which in turn may provide a second subset of the inputs to the ML surrogate 141. The surrogate evaluator 145 may execute ML inference functionality. The surrogate evaluator 145 may determine at least one output derivative of interest. The surrogate evaluator 145 may evaluate gradients and/or Jacobians of specific output quantities or objective functions at specific times. The surrogate evaluator 145 may evaluate surrogate-defined desired quantities with respect to initial states and external input trajectories. The surrogate evaluator 145 may evaluate sparse Jacobian and Hessian blocks by unrolling one or more states. Evaluation of a differentiable surrogate includes computation of its Jacobians and Hessians with respect to all inputs.

Referring now to FIG. 1G, a block diagram depicts one embodiment of a system for generating parameterized data for processing by physics simulation engines and by artificial intelligence engines. As shown in FIG. 1G, the component 140 may execute functionality for training one or more models, such as models that may be used by the surrogate evaluator 145 or the ML surrogate 141. As shown in FIG. 1G, the system 100 may categorize training data and time series batch datasets into states (e.g., physical quantities such as temperatures, pressures, or other measurements; states may be multi-dimensional in the sense that states may represent a field over 2D or 3D space) and external inputs (e.g., control actions made on the system and/or measured disturbances such as flow rates into the system). The system 100 may define n_steps to batch datasets into time-series trajectories that may be used as training samples, resulting in both state and input trajectories. Training specifications may include standard training options such as, without limitation, loggers, number of epochs, devices to run on, and so on. The system 100 may use a surrogate definition to denote a type of architecture that is being trained (e.g., Neural Ordinary Differential Equations, neural state space model, and so on); the surrogate definition may provide a definition of the architecture without including actual data or parameters; therefore, the system 100 may enable reloading of an ML surrogate 141 by parsing its definition and parameters separately. The system 100 may use loss terms to specify options that map to pre-defined callable functions; using symbolic interfaces may simplify a process for defining new loss functions. The system 100 may use a model state to incorporate the definitions of the training state of an ML surrogate 141; model state may include parameters, optimizer data, and the surrogate definition to build an architecture that is ready to train or run inference on. Model states may be saved and loaded by components 140.

In some embodiments, the system 100 includes a plurality of components 140a-n. Each component in the plurality of components 140a-n may execute the same or different tasks. Multi-component functionality may include a description of a class of multi-physics modeling, involving one or more numerical methods or related physics solvers, and/or one or more machine-learned models. Multi-component functionality may include at least one manifestation to describe a system. Multi-component functionality may include at least one manifestation to describe systems-of-systems. In some embodiments, the system 100 provides an enumeration of components 140a-n that may be selected for use alone or in combination with other components 140a-n. In some embodiments, the system provides an enumeration of combinations of components 140a-n that may be selected for use alone or in combination with other components 140a-n or with other combinations of components 140a-n. Such enumerations may be referred to as catalogs of validated machine learning and optimization solution workflows.

As a non-limiting example, in a workflow for end-to-end differentiable shape optimization, a plurality of components 140a-n may each execute a different task. Continuing with this example, a first component 140a may receive input and choose parameters based on the input; a second component 140b may identify and access a file such as a computer aided design (CAD) file; a third component 140c may execute meshing functionality; a fourth component 140d may execute a machine learning mode using the received input, the accessed file, and/or the output of the meshing functionality; a fifth component 140e may execute user-specified functions; a sixth component 140f may select outputs generated by any of the other components in the plurality of components 140a-n and transmit the output to another element in the system, such as the AI engine 107 for optimization or to the user interface module 130 for display to a user. As another non-limiting example, a first component 140a may execute an ML surrogate 141 and provide output generated by the ML surrogate 141 to a second component 140b that executes optimization functionality. As still another non-limiting example, a component 140 may receive output from the modified CAE simulation engine 105 and from the AI engine 107, execute a physics-AI surrogate modeler that undergoes or has completed a process of data generation and surrogate training and surrogate testing and then processes the received input and generates output for visualization (e.g., ML logs and/or surrogate output) and/or deployment (e.g., forecasting and/or analysis); output from the component 140 may be provided to a user, to a software tool, to another component 140b, and/or to the AI engine 107. As another non-limiting example, the component 140a may execute a ML surrogate 141 that is configured to execute multi-physics tools to optimize design, enforce optimality with respect to certain inputs to provide, a threshold level of user-specified robustness, and validate for feasibility given manufacturing constraints. As yet another non-limiting example, a plurality of components 140 may execute a plurality of different types of ML surrogates 141 that may each generate and provide output to another component in the plurality of components 140, which may itself execute additional functionality such as, without limitation, communication, data mapping, spatial coupling, and/or time interpolation for multi-physics, multi-modal coupling, and may then generate and transmit output for visualization (e.g., ML logs and/or surrogate output) and/or deployment (e.g., forecasting and/or analysis). Referring now to FIG. 1H, a block diagram depicts an embodiment of a system for generating parameterized data for processing by physics simulation engines and by artificial intelligence engines. Although the specific embodiment depicted in FIG. 1H represents an example in which the system executes one or more components for emulating subsurface flows and CO2 injection, as shown in FIG. 1H, containerized components 140 generally may be orchestrated with other components 140 to execute different steps in a workflow, without limitation to specific use case. That is, each of the examples described herein may be combined with other configurations of pluralities of components 140a-n depending on a characteristic of a task to be executed. As will be seen from these examples, the type and number of components in the plurality of components 140a-n may vary based on characteristics of a task, user preference, optimization feedback from the AI engine 107, or other factors.

The component 140 and the machine learning surrogate 141 may be referred to as a modified ML surrogate. Therefore, and referring now to FIG. 2B, a block diagram depicts one embodiment of a method 250 for generating data and processing the generated data by at least one physics simulation engine and at least one artificial intelligence engine. The method 250 includes automatically generating, by a data processing engine executing on a computing device, a parameterization representing at least one physics simulation dataset for processing by a modified computer aided engineering (CAE) simulation engine and by a modified machine learning (ML) surrogate, wherein the modified CAE simulation engine is modified to process data exchanged with the modified ML surrogate (252). The method 250 includes transmitting, by the data processing engine, to the modified CAE simulation engine, the generated parameterization (254). The method 250 includes generating, by the modified CAE simulation engine, at least one model of a physical asset (256). The method 250 includes modifying, by the data processing engine, data associated with the at least one model of the physical asset for processing by the modified ML surrogate (258). The method 250 includes providing, by the data processing engine, to the modified ML surrogate, access to the generated parameterization, to the modified data, and to the at least one model of the physical asset (260). The method 250 includes executing, by the modified ML surrogate, at least one workflow using the generated parameterization, the modified data, and the at least one model of the physical asset (262). The method 250 includes generating, by the modified ML surrogate, at least one recommendation associated with the physical asset (264). The method 250 includes transmitting, by the modified ML surrogate, to the modified CAE simulation engine, data to improve a subsequently generated second model of the physical asset (266). The method 250 includes displaying, by the computing device, to a user, at least one of the at least one model of the physical asset and the generated recommendation (268).

Referring now to FIG. 2B in greater detail and in connection with FIGS. 1A-1H and FIG. 2A, the method 250 includes automatically generating, by a data processing engine executing on a computing device, a parameterization representing at least one physics simulation dataset for processing by a modified computer aided engineering (CAE) simulation engine and by a modified machine learning (ML) surrogate, wherein the modified CAE simulation engine is modified to process data exchanged with the modified ML surrogate (252). The method 250 may execute at (252) as described above in connection with FIG. 2A.

The method 250 includes transmitting, by the data processing engine, to the modified CAE simulation engine, the generated parameterization (254). The method 250 may execute at (254) as described above in connection with FIG. 2A.

The method 250 includes generating, by the modified CAE simulation engine, at least one model of a physical asset (256). The method 250 may execute at (256) as described above in connection with FIG. 2A.

The method 250 includes modifying, by the data processing engine, data associated with the at least one model of the physical asset for processing by the modified ML surrogate (258). The method 250 may execute at (258) as described above in connection with FIG. 2A.

The method 250 includes providing, by the data processing engine, to the modified ML surrogate, access to the generated parameterization, to the modified data, and to the at least one model of the physical asset (260). The method 250 may execute at (260) as described above in connection with FIG. 2A.

The method 250 includes executing, by the modified ML surrogate, at least one workflow using the generated parameterization, the modified data, and the at least one model of the physical asset (262). The method 250 may execute at (262) as described above in connection with FIG. 2A, with the component 140 executing the modified ML surrogate 141 in place of the AI engine 107.

The method 250 includes generating, by the modified ML surrogate, at least one recommendation associated with the physical asset (264). The method 250 may execute at (264) as described above in connection with FIG. 2A, with the component 140 executing the modified ML surrogate 141 in place of the AI engine 107.

The method 250 includes transmitting, by the modified ML surrogate, to the modified CAE simulation engine, data to improve a subsequently generated second model of the physical asset (266). The method 250 may execute at (266) as described above in connection with FIG. 2A, with the component 140 executing the modified ML surrogate 141 in place of the AI engine 107.

The method 250 includes displaying, by the computing device, to a user, at least one of the at least one model of the physical asset and the generated recommendation (268). The method 250 may execute at (268) as described above in connection with FIG. 2A.

Although the component 140 described in FIGS. 1F and 2B is described as encapsulating an ML surrogate 141, the component 140 may encapsulate other software tools such as, by way of example and without limitation, physics solvers, CAE models and simulations, and/or programs for executing geometric computing functionality and mesh operations. The component 140 may provide native support for automatic differentiation between heterogeneous software artifacts in distributed and/or cloud contexts, which enables end-to-end differentiable programming and/or hybrid ML and simulation systems. The component 140 may therefore provide functionality that enables improved development, deployment, validation, and/or scaling of differentiable physics programs and pipelines, including, by way of example, pipelines of CAE simulations and ML surrogates.

The system 100 may therefore provide functionality for surrogate modeling and optimization, including model and optimization for digital engineering. The system 100 may include M-inverse engineering templates serving N>>M use-cases via optimization workflows and a plurality of surrogates that provide scaler, low-fidelity functionality (e.g., regression, classification, data assimilation, uncertainty quantification, and experiment design) and/or full-field, high-fidelity functionality (e.g., graph-based, point cloud-based, grid-based, and/or multiphysics coding).

In some embodiments, the system 100 includes non-transitory, computer-readable medium comprising computer program instructions tangibly stored on the non-transitory computer-readable medium, wherein the instructions are executable by at least one processor to perform each of the steps described above in connection with FIGS. 2A-2B.

It should be understood that the systems described above may provide multiple ones of any or each of those components and these components may be provided on either a standalone machine or, in some embodiments, on multiple machines in a distributed system. The phrases ‘in one embodiment,’ ‘in another embodiment,’ and the like, generally mean that the particular feature, structure, step, or characteristic following the phrase is included in at least one embodiment of the present disclosure and may be included in more than one embodiment of the present disclosure. Such phrases may, but do not necessarily, refer to the same embodiment. However, the scope of protection is defined by the appended claims; the embodiments mentioned herein provide examples.

The terms “A or B”, “at least one of A or/and B”, “at least one of A and B”, “at least one of A or B”, or “one or more of A or/and B” used in the various embodiments of the present disclosure include any and all combinations of words enumerated with it. For example, “A or B”, “at least one of A and B” or “at least one of A or B” may mean (1) including at least one A, (2) including at least one B, (3) including either A or B, or (4) including both at least one A and at least one B.

Any step or act disclosed herein as being performed, or capable of being performed, by a computer or other machine, may be performed automatically by a computer or other machine, whether or not explicitly disclosed as such herein. A step or act that is performed automatically is performed solely by a computer or other machine, without human intervention. A step or act that is performed automatically may, for example, operate solely on inputs received from a computer or other machine, and not from a human. A step or act that is performed automatically may, for example, be initiated by a signal received from a computer or other machine, and not from a human. A step or act that is performed automatically may, for example, provide output to a computer or other machine, and not to a human.

Although terms such as “optimize” and “optimal” may be used herein, in practice, embodiments of the present invention may include methods which produce outputs that are not optimal, or which are not known to be optimal, but which nevertheless are useful. For example, embodiments of the present invention may produce an output which approximates an optimal solution, within some degree of error. As a result, terms herein such as “optimize” and “optimal” should be understood to refer not only to processes which produce optimal outputs, but also processes which produce outputs that approximate an optimal solution, within some degree of error.

The systems and methods described above may be implemented as a method, apparatus, or article of manufacture using programming and/or engineering techniques to produce software, firmware, hardware, or any combination thereof. The techniques described above may be implemented in one or more computer programs executing on a programmable computer including a processor, a storage medium readable by the processor (including, for example, volatile and non-volatile memory and/or storage elements), at least one input device, and at least one output device. Program code may be applied to input entered using the input device to perform the functions described and to generate output. The output may be provided to one or more output devices.

Each computer program within the scope of the claims below may be implemented in any programming language, such as assembly language, machine language, a high-level procedural programming language, or an object-oriented programming language. The programming language may, for example, be LISP, PROLOG, PERL, C, C++, C#, JAVA, Python, Rust, Go, or any compiled or interpreted programming language.

Each such computer program may be implemented in a computer program product tangibly embodied in a machine-readable storage device for execution by a computer processor. Method steps may be performed by a computer processor executing a program tangibly embodied on a computer-readable medium to perform functions of the methods and systems described herein by operating on input and generating output. Suitable processors include, by way of example, both general and special purpose microprocessors. Generally, the processor receives instructions and data from a read-only memory and/or a random access memory. Storage devices suitable for tangibly embodying computer program instructions include, for example, all forms of computer-readable devices, firmware, programmable logic, hardware (e.g., integrated circuit chip; electronic devices; a computer-readable non-volatile storage unit; non-volatile memory, such as semiconductor memory devices, including EPROM, EEPROM, and flash memory devices; magnetic disks such as internal hard disks and removable disks; magneto-optical disks; and CD-ROMs). Any of the foregoing may be supplemented by, or incorporated in, specially-designed ASICs (application-specific integrated circuits) or FPGAs (Field-Programmable Gate Arrays). A computer can generally also receive programs and data from a storage medium such as an internal disk (not shown) or a removable disk. These elements will also be found in a conventional desktop or workstation computer as well as other computers suitable for executing computer programs implementing the methods described herein, which may be used in conjunction with any digital print engine or marking engine, display monitor, or other raster output device capable of producing color or gray scale pixels on paper, film, display screen, or other output medium. A computer may also receive programs and data (including, for example, instructions for storage on non-transitory computer-readable media) from a second computer providing access to the programs via a network transmission line, wireless transmission media, signals propagating through space, radio waves, infrared signals, etc.

Referring now to FIGS. 3A, 3B, and 3C, block diagrams depict additional detail regarding computing devices that may be modified to execute novel, non-obvious functionality for implementing the methods and systems described above.

Referring now to FIG. 3A, an embodiment of a network environment is depicted. In brief overview, the network environment comprises one or more clients 302a-302n (also generally referred to as local machine(s) 302, client(s) 302, client node(s) 302, client machine(s) 302, client computer(s) 302, client device(s) 302, computing device(s) 302, endpoint(s) 302, or endpoint node(s) 302) in communication with one or more remote machines 306a-306n (also generally referred to as server(s) 306 or computing device(s) 306) via one or more networks 304.

Although FIG. 3A shows a network 304 between the clients 302 and the remote machines 306, the clients 302 and the remote machines 306 may be on the same network 304. The network 304 can be a local area network (LAN), such as a company Intranet, a metropolitan area network (MAN), or a wide area network (WAN), such as the Internet or the World Wide Web. In some embodiments, there are multiple networks 304 between the clients 302 and the remote machines 306. In one of these embodiments, a network 304′ (not shown) may be a private network and a network 304 may be a public network. In another of these embodiments, a network 304 may be a private network and a network 304′ a public network. In still another embodiment, networks 304 and 304′ may both be private networks. In yet another embodiment, networks 304 and 304′ may both be public networks.

The network 304 may be any type and/or form of network and may include any of the following: a point to point network, a broadcast network, a wide area network, a local area network, a telecommunications network, a data communication network, a computer network, an ATM (Asynchronous Transfer Mode) network, a SONET (Synchronous Optical Network) network, an SDH (Synchronous Digital Hierarchy) network, a wireless network, a wireline network, an Ethernet, a virtual private network (VPN), a software-defined network (SDN), a network within the cloud such as AWS VPC (Virtual Private Cloud) network or Azure Virtual Network (VNet), and a RDMA (Remote Direct Memory Access) network. In some embodiments, the network 304 may comprise a wireless link, such as an infrared channel or satellite band. The topology of the network 304 may be a bus, star, or ring network topology. The network 304 may be of any such network topology as known to those ordinarily skilled in the art capable of supporting the operations described herein. The network may comprise mobile telephone networks utilizing any protocol or protocols used to communicate among mobile devices (including tables and handheld devices generally), including Advanced Mobile Phone System (AMPS), Time Division Multiple Access (TDMA), Code Division Multiple Access (CDMA), Global System for Mobile Communications (GSM), General Packet Radio Service (GPRS), Universal Mobile Telecommunications System (UMTS), or Long-Term Evolution (LTE). In some embodiments, different types of data may be transmitted via different protocols. In other embodiments, the same types of data may be transmitted via different protocols.

A client 302 and a remote machine 306 (referred to generally as computing devices 300 or as machines 300) can be any workstation, desktop computer, laptop or notebook computer, server, portable computer, mobile telephone, mobile smartphone, or other portable telecommunication device, media playing device, a gaming system, mobile computing device, or any other type and/or form of computing, telecommunications or media device that is capable of communicating on any type and form of network and that has sufficient processor power and memory capacity to perform the operations described herein. A client 302 may execute, operate or otherwise provide an application, which can be any type and/or form of software, program, or executable instructions, including, without limitation, any type and/or form of web browser, web-based client, client-server application, an ActiveX control, a JAVA applet, a webserver, a database, an HPC (high performance computing) application, a data processing application, or any other type and/or form of executable instructions capable of executing on client 302.

In one embodiment, a computing device 306 provides functionality of a web server. The web server may be any type of web server, including web servers that are open-source web servers, web servers that execute proprietary software, and cloud-based web servers where a third party hosts the hardware executing the functionality of the web server. In some embodiments, a web server 306 comprises an open-source web server, such as the APACHE servers maintained by the Apache Software Foundation of Delaware. In other embodiments, the web server executes proprietary software, such as the INTERNET INFORMATION SERVICES products provided by Microsoft Corporation of Redmond, WA, the ORACLE IPLANET web server products provided by Oracle Corporation of Redwood Shores, CA, or the ORACLE WEBLOGIC products provided by Oracle Corporation of Redwood Shores, CA.

In some embodiments, the system may include multiple, logically-grouped remote machines 306. In one of these embodiments, the logical group of remote machines may be referred to as a server farm 338. In another of these embodiments, the server farm 338 may be administered as a single entity.

As will be understood by those of skill in the art, in some embodiments, a computing device 300 may provide a virtualization environment. In such embodiments, the computing device 300 may include a hypervisor layer, a virtualization layer, and a hardware layer. The hypervisor layer includes a hypervisor that allocates and manages access to a number of physical resources in the hardware layer (e.g., the processor(s) and disk(s)) by at least one virtual machine executing in the virtualization layer. The virtualization layer includes at least one operating system and a plurality of virtual resources allocated to the at least one operating system. Virtual resources may include, without limitation, a plurality of virtual processors and virtual disks, as well as virtual resources such as virtual memory and virtual network interfaces. The plurality of virtual resources and the operating system may be referred to as a virtual machine. A hypervisor may provide virtual resources to an operating system in any manner that simulates the operating system having access to a physical device. A hypervisor may provide virtual resources to any number of guest operating systems. In some embodiments, a computing device executes one or more types of hypervisors. In these embodiments, hypervisors may be used to emulate virtual hardware, partition physical hardware, virtualize physical hardware, and execute virtual machines that provide access to computing environments. Hypervisors may include those manufactured by VMWare, Inc., of Palo Alto, California; the XEN hypervisor, an open source product whose development is overseen by the open source Xen. org community; the KVM hypervisor, an open source product whose development is overseen by the open source Linux community; HyperV, VirtualServer or virtual PC hypervisors provided by Microsoft, Amazon Nitro, Amazon Firecracker, or others. In some embodiments, a computing device executing a hypervisor that creates a virtual machine platform on which guest operating systems may execute is referred to as a host server. In some embodiments, a hypervisor executes within an operating system executing on a computing device. In one of these embodiments, a computing device executing an operating system and a hypervisor may be said to have a host operating system (the operating system executing on the computing device), and a guest operating system (an operating system executing within a computing resource partition provided by the hypervisor). In other embodiments, a hypervisor interacts directly with hardware on a computing device, instead of executing on a host operating system. In one of these embodiments, the hypervisor may be said to be executing on “bare metal,” referring to the hardware comprising the computing device. In some embodiments, the hypervisor controls processor scheduling and memory partitioning for a virtual machine executing on the computing device. In one of these embodiments, the hypervisor controls the execution of at least one virtual machine. In another of these embodiments, the hypervisor presents at least one virtual machine with an abstraction of at least one hardware resource provided by the computing device. In other embodiments, the hypervisor controls whether and how physical processor capabilities are presented to the virtual machine. In one embodiment, the guest operating system, in conjunction with the virtual machine on which it executes, forms a fully-virtualized virtual machine which is not aware that it is a virtual machine; such a machine may be referred to as a “Domain U HVM (Hardware Virtual Machine)”. In another embodiment, a fully-virtualized machine includes software emulating a Basic Input/Output System (BIOS) in order to execute an operating system within the fully-virtualized machine. In still another embodiment, a fully-virtualized machine may include a driver that provides functionality by communicating with the hypervisor; in such an embodiment, the driver is typically aware that it executes within a virtualized environment. In another embodiment, the guest operating system, in conjunction with the virtual machine on which it executes, forms a paravirtualized virtual machine, which is aware that it is a virtual machine; such a machine may be referred to as a “Domain U PV virtual machine”. In another embodiment, a paravirtualized machine includes additional drivers that a fully-virtualized machine does not include.

FIGS. 3B and 3C depict block diagrams of a computing device 400 useful for practicing an embodiment of the client 302 or a remote machine 306. As shown in FIGS. 3B and 3C, each computing device 300 includes a central processing unit 321, and a main memory unit 322. As shown in FIG. 3B, a computing device 300 may include a storage device 328, an installation device 316, a network interface 318, an Input/Output (I/O) controller 323, display devices 324a-n, a keyboard 326, a pointing device 327, such as a mouse, and one or more other I/O devices 330a-n. The storage device 328 may include, without limitation, an operating system and software. As shown in FIG. 3C, each computing device 300 may also include additional optional elements, such as a memory port 303, a bridge 370, one or more input/output devices 330a-(generally referred to as input/output devices 330), and a cache memory 340 in communication with the central processing unit 321.

The central processing unit 321 is any logic circuitry that responds to and processes instructions fetched from the main memory unit 322. In many embodiments, the central processing unit 321 is provided by a microprocessor unit, such as: those manufactured by Intel Corporation of Mountain View, CA; those manufactured by Motorola Corporation of Schaumburg, IL; those manufactured by Transmeta Corporation of Santa Clara, CA; those manufactured by International Business Machines of White Plains, NY; or those manufactured by Advanced Micro Devices of Sunnyvale, CA. Other examples include RISC-V processors, SPARC processors, ARM processors, processors used to build UNIX/LINUX “white” boxes, and processors for mobile devices. The computing device 300 may be based on any of these processors, or any other processor capable of operating as described herein.

Main memory unit 322 may be one or more memory chips capable of storing data and allowing any storage location to be directly accessed by the central processing unit 321, which may be a microprocessor. The main memory unit 322 may be based on any available memory chips capable of operating as described herein. In the embodiment shown in FIG. 3B, the central processing unit 321 communicates with main memory unit 322 via a system bus 350. FIG. 3C depicts an embodiment of a computing device 300 in which the processor communicates directly with main memory unit 322 via a memory port 303. FIG. 3C also depicts an embodiment in which the central processing unit 321 communicates directly with cache memory 340 via a secondary bus, sometimes referred to as a backside bus. In other embodiments, the central processing unit 321 communicates with cache memory 340 using the system bus 350.

In the embodiment shown in FIG. 3B, the central processing unit 321 communicates with various I/O devices 330 via the system bus 350. Various buses may be used to connect the central processing unit 321 to any of the I/O devices 330, including a Video Electronics Standards Association Vesa Local Bus (VESA VL bus), an Industry Standard Architecture (ISA bus), an Extended Industry Standard Architecture (EISA) bus, a MicroChannel Architecture (MCA) bus, a Peripheral Component Interconnect (PCI) bus, a Peripheral Component Interconnect Extended (PCI-X) bus, a PCI-Express bus, or a NuBus. For embodiments in which the I/O device is a video display device 324, the central processing unit 321 may use an Advanced Graphics Port (AGP) to communicate with the display device 324. FIG. 3C depicts an embodiment of a computing device 300 in which the central processing unit 321 also communicates directly with an I/O device 330b via, for example, HYPERTRANSPORT, RAPIDIO, or INFINIBAND communications technology.

One or more of a wide variety of I/O devices 330a-n may be present in or connected to the computing device 300, each of which may be of the same or different type and/or form. Input devices include keyboards, mice, trackpads, trackballs, microphones, scanners, cameras, and drawing tablets. Output devices include video displays, speakers, inkjet printers, laser printers, 3D printers, and dye-sublimation printers. The I/O devices may be controlled by an I/O controller 323 as shown in FIG. 3B. Furthermore, an I/O device may also provide storage and/or an installation device 316 for the computing device 300. In some embodiments, the computing device 300 may provide USB connections (not shown) to receive handheld USB storage devices such as the USB Flash Drive line of devices manufactured by Twintech Industry, Inc. of Los Alamitos, CA.

Referring still to FIG. 3B, the computing device 400 may support any suitable installation device 316, such as hardware for receiving and interacting with removable storage; e.g., disk drives of any type, Compact Disc (CD) drives of any type, Digital Versatile Disc-Read Only Memory (DVD) drives, tape drives of various formats, Universal Serial Bus (USB) devices, external hard drives, or any other device suitable for installing software and programs. In some embodiments, the computing device 300 may provide functionality for installing software over a network 304. The computing device 300 may further comprise a storage device, such as one or more hard disk drives or redundant arrays of independent disks, for storing an operating system and other software. Alternatively, the computing device 300 may rely on memory chips for storage instead of hard disks.

Furthermore, the computing device 300 may include a network interface 318 to interface to the network 304 through a variety of connections including, but not limited to, standard telephone lines, Local Area Network (LAN) or Wide Area Network (WAN) links (e.g., 802.11, T1, T3, 56 kb, X.25, Systems Network Architecture (SNA), DECNET, Remote Direct Memory Access (RDMA)), broadband connections (e.g., Integrated Services Digital Network (ISDN), Frame Relay, Asynchronous Transfer Mode (ATM), Gigabit Ethernet, Ethernet-over-Synchronous Optical Network), wireless connections, virtual private network (VPN) connections, or some combination of any or all of the above. Connections can be established using a variety of communication protocols (e.g., Transport Control Protocol/Internet Protocol (TCP/IP), Internetwork Packet Exchange (IPX), Sequenced Packet Exchange (SPX), NetBIOS, Ethernet, Attached Resource Computer Network (ARCNET), Synchronous Optical Network (SONET), Synchronized Digital Hierarchy (SDH), Fiber Distributed Data Interface (FDDI), RS232, IEEE 802.11, IEEE 802.11a, IEEE 802.11b, IEEE 802.11g, IEEE 802.11n, 802.15.4, Bluetooth, ZIGBEE, CDMA, GSM, Worldwide Interoperability for Microwave Access (WiMax), and direct asynchronous connections). In one embodiment, the computing device 300 communicates with other computing devices 300′ via any type and/or form of gateway or tunneling protocol such as Generic Routing Encapsulation (GRE), Virtual Extensible Local Area Network (VXLAN), Intern Protocol in Internet Protocol (IPIP), System Integration Testing (SIT), Internet Protocol version 6 Tunneling (ip6tnl), Virtual Tunnel Interface (VTI) and Virtual Tunnel Interface for Internet Protocol version 6 (VTI6), Internet Protocol version 6 Generic Routing Encapsulation (IP6GRE), Generic User Datagram Protocol (UDP) Encapsulation (GUE), Generic Network Virtualization Encapsulation (GENEVE), Encapsulated Remote Switched Port Analyzer (ERSPAN), Secure Socket Layer (SSL) or Transport Layer Security (TLS). The network interface 318 may comprise a built-in network adapter, network interface card, Personal Computer Memory Card International Association (PCMCIA) network card, card bus network adapter, wireless network adapter, USB network adapter, modem, or any other device suitable for interfacing the computing device 300 to any type of network capable of communication and performing the operations described herein.

In further embodiments, an I/O device 330 may be a bridge between the system bus 350 and an external communication bus, such as a USB bus, an Apple Desktop Bus, an RS-232 serial connection, a Small Computer Systems Interface (SCSI) bus, a FireWire bus, a FireWire 800 bus, an Ethernet bus, an AppleTalk bus, a Gigabit Ethernet bus, an Asynchronous Transfer Mode bus, a High-Performance Parallel Interface (HIPPI) bus, a Super HIPPI bus, a SerialPlus bus, a Scalable Coherent Interface (SCI)/Linux-Apache-MySQL-PHP Perl or Python (LAMP) bus, a FibreChannel bus, or a Serial Attached small computer system interface bus.

A computing device 300 of the sort depicted in FIGS. 3B and 3C typically operates under the control of operating systems, which control scheduling of tasks and access to system resources. The computing device 300 can be running any operating system such as any of the versions of the MICROSOFT WINDOWS operating systems, the different releases of the UNIX and LINUX operating systems, any version of the MAC OS for Macintosh computers, any embedded operating system, any real-time operating system, any open source operating system, any proprietary operating system, any operating systems for mobile computing devices, or any other operating system capable of running on the computing device and performing the operations described herein. Typical operating systems include, but are not limited to: WINDOWS 7, WINDOWS 8, WINDOWS VISTA, WINDOWS 10, and WINDOWS 11 all of which are manufactured by Microsoft Corporation of Redmond, WA; MAC OS manufactured by Apple Inc. of Cupertino, CA; OS/2 manufactured by International Business Machines of Armonk, NY; Red Hat Enterprise Linux, a Linux-variant operating system distributed by Red Hat, Inc., of Raleigh, NC; Ubuntu, a freely-available operating system distributed by Canonical Ltd. of London, England; CentOS, a freely-available operating system distributed by the centos. org community; SUSE Linux, a freely-available operating system distributed by SUSE, or any type and/or form of a Unix operating system, among others.

Having described certain embodiments of methods and systems for generating parameterized data for processing by physics simulation engines and by artificial intelligence engines, it will be apparent to one of skill in the art that other embodiments incorporating the concepts of the disclosure may be used. Therefore, the disclosure should not be limited to certain embodiments, but rather should be limited only by the spirit and scope of the following claims.

1. A method for generating data and processing the generated data by at least one physics simulation engine and at least one artificial intelligence engine, the method comprising:
(a) automatically generating, by a data processing engine executing on a computing device, a parameterization representing at least one physics simulation dataset for processing by a modified computer aided engineering (CAE) simulation engine and by an artificial intelligence (AI) engine, wherein the modified CAE simulation engine is modified to process data exchanged with the AI engine, and wherein the AI engine executes at least one machine learning model;
(b) transmitting, by the data processing engine, to the modified CAE simulation engine, the generated parameterization;
(c) generating, by the modified CAE simulation engine, at least one model of a physical asset;
(d) modifying, by the data processing engine, data associated with the at least one model of the physical asset for processing by the AI engine;
(e) providing, by the data processing engine, to the AI engine, access to the generated parameterization, to the modified data, and to the at least one model of the physical asset;
(f) executing, by the AI engine, at least one workflow using the generated parameterization, the modified data, and the at least one model of the physical asset;
(g) generating, by the AI engine, at least one recommendation associated with the physical asset;
(h) transmitting, by the AI engine, to the modified CAE simulation engine, data to improve a subsequently generated second model of the physical asset; and
(i) displaying, by the computing device, to a user, at least one of the at least one model of the physical asset and the generated recommendation.

2. The method of claim 1, wherein (a) further comprises automatically parameterizing, by the data processing engine executing on the computing device, the at least one physics simulation dataset for processing by the modified CAE simulation engine and by the AI engine, wherein the AI engine executes the at least one machine learning model and at least one algorithm.

3. The method of claim 1 wherein (c) further comprises executing, by the modified CAE simulation engine a plurality of physics solvers to generate the at least one model of the physical asset.

4. The method of claim 3, further comprising orchestrating, by the modified CAE simulation engine execution of the plurality of physics solvers, based upon an output of processing the generated parameterization.

5. The method of claim 1 further comprising executing, by the modified CAE simulation engine a plurality of computational engineering tools to generate the at least one model of the physical asset.

6. The method of claim 5, further comprising orchestrating, by the modified CAE simulation engine execution of the plurality of computational engineering tools, based upon an output of processing the generated parameterization.

7. The method of claim 1 further comprising, subsequent to (f), generating, by the AI engine, at least one output.

8. The method of claim 1 further comprising generating, by the AI engine, output including at least one inference.

9. The method of claim 1 further comprising generating, by the AI engine, output including at least one prediction.

10. The method of claim 1 further comprising generating, by the AI engine, output including at least one classification.

11. The method of claim 1 further comprising generating, by the AI engine, output including at least one estimate of a level of confidence.

12. The method of claim 1 wherein (g) further comprises generating at least one recommendation including an optimization for improving a level of performance of the physical asset.

13. The method of claim 1 further comprising calibrating, by the AI engine, in communication with the modified CAE simulation engine, the parameterized at least one physics simulation dataset.

14. The method of claim 1 further comprising calibrating, by the AI engine, in communication with the modified CAE simulation engine, the at least one model of the physical asset.

15. A method for generating data and processing the generated data by at least one physics simulation engine and at least one machine learning engine, the method comprising:
(a) automatically generating, by a data processing engine executing on a computing device, a parameterization representing at least one physics simulation dataset for processing by a modified computer aided engineering (CAE) simulation engine and by a modified machine
learning (ML) surrogate, wherein the modified CAE simulation engine is modified to process data exchanged with the modified ML surrogate;
(b) transmitting, by the data processing engine, to the modified CAE simulation engine, the generated parameterization;
(c) generating, by the modified CAE simulation engine, at least one model of a physical asset;
(d) modifying, by the data processing engine, data associated with the at least one model of the physical asset for processing by the modified ML surrogate;
(e) providing, by the data processing engine, to the modified ML surrogate, access to the generated parameterization, to the modified data, and to the at least one model of the physical asset;
(f) executing, by the modified ML surrogate, at least one workflow using the generated parameterization, the modified data, and the at least one model of the physical asset;
(g) generating, by the modified ML surrogate, at least one recommendation associated with the physical asset;
(h) transmitting, by the modified ML surrogate, to the modified CAE simulation engine, data to improve a subsequently generated second model of the physical asset; and
(i) displaying, by the computing device, to a user, at least one of the at least one model of the physical asset and the generated recommendation.
